(19) United States
(12) Patent Application Publication
(10) Pub. No.: US 2024/0079200 A1
(43) Pub. Date: Mar. 7, 2024

(54) MULTI-ELECTRON BEAM IMAGE ACQUIRING APPARATUS AND MULTI-ELECTRON BEAM IMAGE ACQUIRING METHOD

(71) Applicant: NuFlare Technology, Inc., Yokohama-shi (JP)

(72) Inventors: Kazuhiko INOUE, Yokohama-shi (JP); Atsushi ANDO, Edogawa-ku (JP); Munehiro OGASAWARA, Hiratsuka-shi (JP)

(73) Assignee: NuFlare Technology, Inc., Yokohama-shi (JP)

(21) Appl. No.: 18/505,216

(22) Filed: Nov. 9, 2023

Related U.S. Application Data
(63) Continuation of application No. PCT/JP2022/018962, filed on Apr. 26, 2022.

(30) Foreign Application Priority Data
May 11, 2021 (JP) 2021-080642

(51) Int. Cl. H01J 37/145; H01J 37/244

(52) U.S. Cl. CPC H01J 37/145; H01J 37/244; H01J 2237/1508; H01J 2237/1516

(57) ABSTRACT

A multi-electron beam image acquiring apparatus includes a stage configured to mount thereon a substrate, an illumination optical system configured to apply multiple primary electron beams to the substrate, a plurality of multipole lenses including at least two stages of multipole lenses, arranged at positions common to a trajectory of the multiple primary electron beams and a trajectory of multiple secondary electron beams which are emitted because the substrate is irradiated with the multiple primary electron beams and each configured to include at least four electrodes and at least four magnetic poles, and a multi-detector configured to detect the multiple secondary electron beams separated from the trajectory of the multiple primary electron beams, wherein one of the plurality of multipole lenses separates the multiple secondary electron beams from the trajectory of the multiple primary electron beams.

### CROSS-REFERENCE TO RELATED APPLICATION

This application is a continuation application based upon and claims the benefit of priority from prior Japanese Patent Application No. 2021-080642 (application number) filed on May 11, 2021 in Japan, and International Application PCT/JP2022/018962, the International Filing Date of which is Apr. 26, 2022. The contents described in JP2021-080642 and PCT/JP2022/018962 are incorporated herein by reference.

### BACKGROUND OF THE INVENTION

### Field of the Invention

Embodiments of the present invention relate to a multi-beam image acquiring apparatus and a multi-beam image acquiring method, and, for example, relate to an image acquiring method employed by a multi-beam inspection apparatus that inspects patterns by using secondary electron images resulting from irradiation with multiple primary electron beams.

### Description of Related Art

With recent progress in high integration and large capacity of the LSI (Large Scale Integrated circuits), the line width (critical dimension) required for circuits of semiconductor elements is becoming increasingly narrower. Since LSI manufacturing requires an enormous production cost, it is essential to improve the yield. However, as typified by 1 gigabit DRAMs (Dynamic Random Access Memories), the size of patterns that make up LSIs becomes the order of nanometers from submicrons. Also, in recent years, with miniaturization of dimensions of LSI patterns formed on a semiconductor wafer, dimensions to be detected as a pattern defect have become extremely small. Therefore, the pattern inspection apparatus which inspects defects of ultrafine patterns exposed (transferred) to a semiconductor wafer needs to be highly accurate.

The inspection apparatus acquires a pattern image by, for example, irradiating an inspection target substrate with multiple electron beams and detecting a secondary electron corresponding to each beam emitted from the inspection target substrate. As an inspection method, there is known a method of comparing a measured image acquired by imaging a pattern formed on a substrate with design data or with another measured image acquired by imaging an identical pattern on the same substrate. For example, as pattern inspection methods, there are “die-to-die inspection” and “die-to-database inspection”. Specifically, the “die-to-die inspection” method compares data of measured images acquired by imaging identical patterns at different positions on the same substrate. The “die-to-database inspection” method generates design image data (reference image) based on pattern design data, and compares it with a measured image being measured data acquired by imaging a pattern. Acquired images are transmitted as measured data to a comparison circuit. After performing alignment between the images, the comparison circuit compares the measured data with reference data according to an appropriate algorithm, and determines that there is a pattern defect if the compared data do not match each other.

In the case of acquiring an inspection image by using multiple electron beams, the pitch between beams needs to be narrowed in order to achieve high resolution, for example. If the beam pitch has been narrowed, there occurs a problem that inter-beam crosstalk is easily generated in the detection system. Specifically, an E×B (E cross B) separator in which the electric field and the magnetic field cross each other is arranged on the trajectory of a primary electron beam to separate secondary electron beams from primary electron beams. The E×B separator is arranged at a position conjugate to the image plane of the primary electron beam where the influence of E×B is small. Then, the primary electron beam is imaged on the surface of a target object by an objective lens. With respect to the primary electron beam and the secondary electron beam, the energy of an irradiation electron incident on the target object surface is different from that of a generated secondary electron. Therefore, when an intermediate image plane of a primary electron beam is formed on the surface of the E×B separator, a secondary electron beam having passed through the objective lens forms an intermediate image plane before reaching the E×B separator. Thus, the secondary electron beam spreads without forming an intermediate image plane on the surface of the E×B separator. For this reason, an aberration generated when separated by the E×B separator is large. Accordingly, there is a problem that multiple secondary electron beams may overlap with each other on the detector, resulting in difficulty in detecting individually. In other words, there is a problem of easily producing a crosstalk between beams. This problem is not limited to the inspection apparatus, and may similarly occur in the apparatus, in general, which acquires an image by using multiple electron beams.

There is disclosed a method in which a Wien filter of a four-stage multipole lens for correcting an on-axis chromatic aberration is arranged in the secondary electron optical system away from the primary electron optical system in order to correct an on-axis chromatic aberration of a separated secondary electron (e.g., refer to Japanese Patent Application Laid-open (JP-A) No. 2006-244875).

### BRIEF SUMMARY OF THE INVENTION

According to one aspect of the present invention, a multi-electron beam image acquiring apparatus includes
a stage configured to mount thereon a substrate,
an illumination optical system configured to apply multiple primary electron beams to the substrate,
a plurality of multipole lenses including at least two stages of multipole lenses, arranged at positions common to a trajectory of the multiple primary electron beams and a trajectory of multiple secondary electron beams which are emitted because the substrate is irradiated with the multiple primary electron beams and each configured to include at least four electrodes and at least four magnetic poles, and
a multi-detector configured to detect the multiple secondary electron beams separated from the trajectory of the multiple primary electron beams,
wherein one of the plurality of multipole lenses separates the multiple secondary electron beams from the trajectory of the multiple primary electron beams.

According to another aspect of the present invention, a multi-electron beam image acquiring method includes
applying, by an illumination optical system, multiple primary electron beams to a substrate mounted on a stage,
exerting a lens effect on multiple secondary electron beams, which are emitted because the substrate is irradiated with the multiple primary electron beams, by a plurality of multipole lenses including at least two stages of multipole lenses and each including at least four electrodes and at least four magnetic poles,
separating the multiple secondary electron beams from a trajectory of the multiple primary electron beams by one of the plurality of multipole lenses, and
detecting the multiple primary electron beams having been separated.

### BRIEF DESCRIPTION OF THE DRAWINGS

FIG. 1 is a configuration diagram of a pattern inspection apparatus according to a first embodiment;

FIG. 2 is a conceptual diagram of a configuration of a shaping aperture array substrate according to the first embodiment;

FIG. 3A is a diagram for explaining a configuration and a deflection action of an E×B multipole lens according to the first embodiment;

FIG. 3B is a diagram for explaining a configuration and a deflection action of an E×B multipole lens according to the first embodiment;

FIG. 3C is a diagram for explaining a configuration and a deflection action of an E×B multipole lens according to the first embodiment;

FIG. 4 is a diagram showing an example of trajectories of multiple primary electron beams and multiple secondary electron beams according to a comparative example of the first embodiment;

FIG. 5 is a diagram for explaining a lens effect of an E×B multipole lens on multiple primary electron beams according to the first embodiment;

FIG. 6 is a diagram for explaining a lens effect of an E×B multipole lens on multiple secondary electron beams according to the first embodiment;

FIG. 7 is a diagram showing an example of trajectories of multiple primary electron beams and multiple secondary electron beams in a quadrupole field according to the first embodiment;

FIG. 8 is a diagram for explaining an effect of a two-stage quadrupole lens according to the first embodiment;

FIG. 9 shows magnification equations based on a two-stage quadrupole field according to the first embodiment;

FIG. 10A is an illustration showing an example of the state of multiple secondary electron beams at an image plane of a two-stage quadrupole field according to the first embodiment;

FIG. 10B is an illustration showing an example of the state of multiple secondary electron beams at an image plane of a two-stage quadrupole field according to the first embodiment;

FIG. 10C is an illustration showing an example of the state of multiple secondary electron beams at an image plane of a two-stage quadrupole field according to the first embodiment;

FIG. 11 is an illustration showing an example of a force direction by a quadrupole field and a deflection direction by a deflection field according to the first embodiment;

FIG. 12 is an illustration showing examples of the trajectories of multiple secondary electron beams and multiple primary electron beams in the state where a deflection field is combined with a two-stage quadrupole field according to the first embodiment;

FIG. 13A is an illustration showing an example of the state of multiple secondary electron beams at an image plane of a field where a deflection field is combined with a two-stage quadrupole field according to the first embodiment;

FIG. 13B is an illustration showing an example of the state of multiple secondary electron beams at an image plane of a field where a deflection field is combined with a two-stage quadrupole field according to the first embodiment;

FIG. 13C is an illustration showing an example of the state of multiple secondary electron beams at an image plane of a field where a deflection field is combined with a two-stage quadrupole field according to the first embodiment;

FIG. 14 is a configuration diagram of a pattern inspection apparatus according to a first modified example of the first embodiment;

FIG. 15 is a diagram showing an example of a trajectory of multiple secondary electron beams in a quadrupole field according to the first modified example of the first embodiment;

FIG. 16 is a configuration diagram of a pattern inspection apparatus according to a second modified example of the first embodiment;

FIG. 17A is an illustration showing an example of the third multipole lens according to the second modified example of the first embodiment;

FIG. 17B is an illustration showing an example of the third multipole lens according to the second modified example of the first embodiment;

FIG. 18 is an illustration showing an example of a plurality of chip regions formed on a semiconductor substrate, according to the first embodiment;

FIG. 19 is an illustration describing image acquiring processing according to the first embodiment; and

FIG. 20 is a configuration diagram of a pattern inspection apparatus according to a third modified example of the first embodiment.

### DETAILED DESCRIPTION OF THE INVENTION

Embodiments below provide an apparatus and method that can reduce aberration which is generated when multiple secondary electron beams are separated from multiple primary electron beams by an E×B separator.

Embodiments below describe a multi-electron beam inspection apparatus as an example of a multi-electron beam image acquiring apparatus. However, the image acquiring apparatus is not limited to the inspection apparatus, and any apparatus is acceptable as long as it acquires an image by using multiple beams.

### First Embodiment

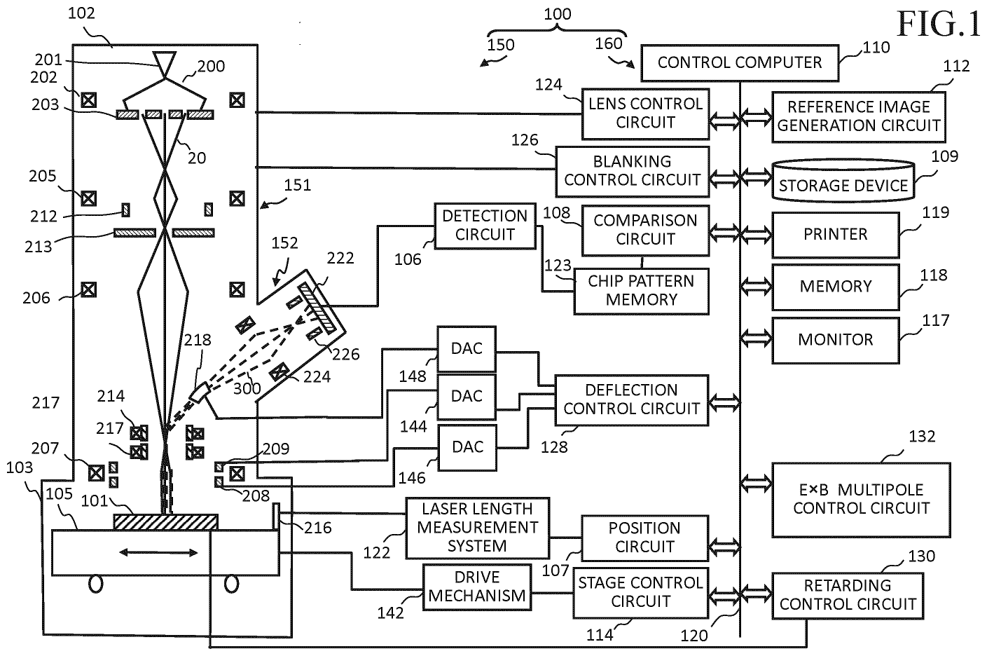

FIG. 1 is a configuration diagram of a pattern inspection apparatus according to a first embodiment. In FIG. 1, an inspection apparatus 100 which inspects patterns formed on the substrate is an example of a multi-electron beam inspection apparatus. Also, the inspection apparatus 100 is an example of a multi-electron beam image acquiring apparatus. The inspection apparatus 100 includes an image acquisition mechanism 150 and a control system circuit 160 (control unit). The image acquisition mechanism 150 includes an electron beam column 102 (electron optical column), an inspection chamber 103, a detection circuit 106, a chip pattern memory 123, a stage drive mechanism 142, and a laser length measurement system 122. In the electron beam column 102, there are arranged an electron gun 201, an electromagnetic lens 202, a shaping aperture array substrate 203, an electromagnetic lens 205, a collective deflector 212, a limiting aperture substrate 213, electromagnetic lenses 206 and 207, a main deflector 208, a sub deflector 209, a plurality of multipole lenses including at least two stages of multipole lenses (an E×B multipole lens 214 and an E×B multipole lens 217), a deflector 218, an electromagnetic lens 224, a deflector 226, and a multi-detector 222. In an example of FIG. 1, two stages of multipole lenses are configured by the E×B multipole lens 214 and the E×B multipole lens 217.

A primary electron optical system 151 (illumination optical system) is composed of the electron gun 201, the electromagnetic lens 202, the shaping aperture array substrate 203, the electromagnetic lens 205, the collective deflector 212, the limiting aperture substrate 213, the electromagnetic lens 206, the electromagnetic lens 207 (objective lens), the main deflector 208, and the sub deflector 209. A secondary electron optical system 152 (detection optical system) is composed of the electromagnetic lens 207 (objective lens), a plurality of two or more multipole lenses, the deflector 218, the electromagnetic lens 224 and the deflector 226.

As the plurality of multipole lenses, in the example of FIG. 1, the E×B multipole lens 214 and the E×B multipole lens 217 are arranged. The E×B multipole lenses 214 and 217 are arranged at positions common to the trajectory of the multiple primary electron beams 20 and that of multiple secondary electron beams 300. In the case of FIG. 1, the E×B multipole lenses 214 and 217 are located between the electromagnetic lenses 206 and 207.

In the inspection chamber 103, there is disposed a stage 105 movable at least in the x and y directions. A substrate 101 (target object) to be inspected is placed on the stage 105. The substrate 101 may be an exposure mask substrate, or a semiconductor substrate such as a silicon wafer. In the case of the substrate 101 being a semiconductor substrate, a plurality of chip patterns (wafer die) are formed on the semiconductor substrate. In the case of the substrate 101 being an exposure mask substrate, a chip pattern is formed on the exposure mask substrate. The chip pattern is composed of a plurality of figure patterns. When the chip pattern formed on the exposure mask substrate is exposed/transferred onto the semiconductor substrate a plurality of times, a plurality of chip patterns (wafer die) are formed on the semiconductor substrate. The case of the substrate 101 being a semiconductor substrate is mainly described below. The substrate 101 is placed, with its pattern-forming surface facing upward, on the stage 105, for example. Further, on the stage 105, there is disposed a mirror 216 which reflects a laser beam for measuring a laser length emitted from the laser length measurement system 122 arranged outside the inspection chamber 103.

The multi-detector 222 is connected, at the outside of the electron beam column 102, to the detection circuit 106. The detection circuit 106 is connected to the chip pattern memory 123.

In the control system circuit 160, a control computer 110 which controls the whole of the inspection apparatus 100 is connected, through a bus 120, to a position circuit 107, a comparison circuit 108, a reference image generation circuit 112, a stage control circuit 114, a lens control circuit 124, a blanking control circuit 126, a deflection control circuit 128, a retarding control circuit 130, an E×B multipole control circuit 132, a storage device 109 such as a magnetic disk drive, a monitor 117, a memory 118, and a printer 119. The deflection control circuit 128 is connected to DAC (digital-to-analog conversion) amplifiers 144, 146 and 148. The DAC amplifier 146 is connected to the main deflector 208, and the DAC amplifier 144 is connected to the sub deflector 209. The DAC amplifier 148 is connected to the deflector 218.

The chip pattern memory 123 is connected to the comparison circuit 108. The stage 105 is driven by the drive mechanism 142 under the control of the stage control circuit 114. In the drive mechanism 142, a drive system such as a three (x-, y-, and θ-) axis motor driving in the directions of x, y, and θ in the stage coordinate system is configured, and therefore, the stage 105 can be moved in the x, y, and θ directions. A step motor, for example, can be used as each of these x, y, and θ motors (not shown). The stage 105 is movable in the horizontal direction and the rotation direction by the x-, y-, and θ-axis motors. The movement position of the stage 105 is measured by the laser length measurement system 122, and supplied (transmitted) to the position circuit 107. Based on the principle of laser interferometry, the laser length measurement system 122 measures the position of the stage 105 by receiving a reflected light from the mirror 216. In the stage coordinate system, the x, y, and θ directions are set, for example, with respect to a plane perpendicular to the optical axis of the multiple primary electron beams 20.

The electromagnetic lenses 202, 205, 206, 207, and 224 are controlled by the lens control circuit 124. The collective deflector 212 is composed of two or more electrodes (or poles), and each electrode is controlled by the blanking control circuit 126 through a DAC amplifier (not shown). The sub deflector 209 is composed of four or more electrodes (or poles), and each electrode is controlled by the deflection control circuit 128 through the DAC amplifier 144. The main deflector 208 is composed of four or more electrodes (or poles), and each electrode is controlled by the deflection control circuit 128 through the DAC amplifier 146. The deflector 218 is configured by a two-stage deflector composed of four or more electrodes (or poles), and each electrode is controlled by the deflection control circuit 128 through the DAC amplifier 148. The deflector 226 is composed of four or more electrodes (or poles), and each electrode is controlled by the deflection control circuit 128 through a DAC amplifier (not shown). The retarding control circuit 130 applies a desired retarding potential to the substrate 101 in order to adjust the energy of the multiple primary electron beams 20 with which the substrate 101 is irradiated.

The E×B multipole lenses 214 and 217 are controlled by the E×B multipole lens control circuit 132.

To the electron gun 201, there is connected a high-voltage power supply circuit (not shown). The high-voltage power supply circuit applies an acceleration voltage between a filament and an extraction electrode (which are not shown) in the electron gun 201. In addition to applying the acceleration voltage, a voltage is applied to a predetermined extraction electrode (Wehnelt), and the cathode is heated to a predetermined temperature, and thereby, electrons from the cathode are accelerated to be emitted as an electron beam 200.

FIG. 1 shows configuration elements necessary for describing the first embodiment. It should be understood that other configuration elements generally necessary for the inspection apparatus 100 may also be included therein.

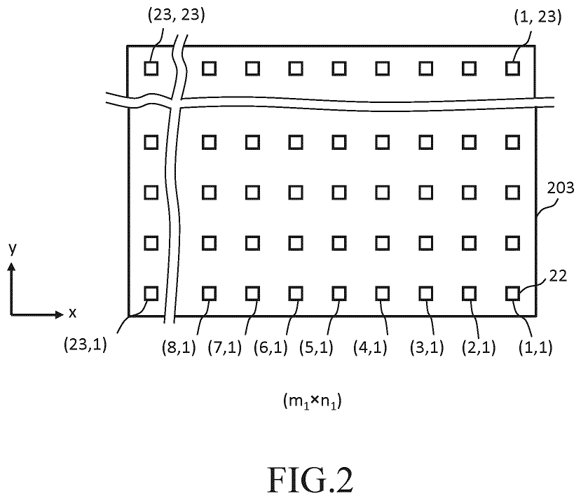

FIG. 2 is a conceptual diagram of a configuration of a shaping aperture array substrate according to the first embodiment. As shown in FIG. 2, holes (openings) 22 of m₁ columns wide (width in the x direction) (each column in the y direction) and n₁ rows long (length in the y direction) (each row in the x direction), where each of m₁ and n₁ is an integer of 2 or more, are two-dimensionally formed in the x and y directions at a predetermined arrangement pitch in the shaping aperture array substrate 203. In the case of FIG. 2, holes (openings) 22 of 23×23 are formed. Each of the holes 22 is a rectangle (including a square) having the same dimension, shape, and size. Alternatively, each of the holes 22 may be a circle with the same outer diameter. The multiple primary electron beams 20 are formed by letting portions of the electron beam 200 individually pass through a corresponding one of a plurality of holes 22. The shaping aperture array substrate 203 is an example of a multiple beam forming mechanism which forms multiple primary electron beams.

The image acquisition mechanism 150 acquires an inspection image of a figure pattern formed on the substrate 101 by using multiple electron beams. Hereinafter, operations of the image acquisition mechanism 150 in the inspection apparatus 100 will be explained.

The electron beam 200 emitted from the electron gun 201 (emission source) is refracted by the electromagnetic lens 202, and illuminates the whole of the shaping aperture array substrate 203. As shown in FIG. 2, a plurality of holes 22 (openings) are formed in the shaping aperture array substrate 203. The region including all of the plurality of holes 22 is irradiated by the electron beam 200. The multiple primary electron beams 20 are formed by letting portions of the electron beam 200 applied to the positions of the plurality of holes 22 individually pass through a corresponding one of the plurality of holes 22 in the shaping aperture array substrate 203.

The formed multiple primary electron beams 20 are individually refracted by the electromagnetic lenses 205 and 206, and travel, while repeating forming an intermediate image and a crossover, to the E×B multipole lens 214 located on an intermediate image plane (position conjugate to the image plane: I. I. P.) of each beam of the multiple primary electron beams 20. Then, they travel to the electromagnetic lens 207 after passing through the E×B multipole lenses 214 and 217. By disposing the limiting aperture substrate 213 with limited passage holes close to a crossover position of the multiple primary electron beams 20, it becomes possible to block scattered beams. Further, by collectively deflecting all the multiple primary electron beams 20 by the collective deflector 212 and blocking the entire multiple primary electron beams 20 by the limiting aperture substrate 213, it becomes possible to perform blanking of all the multiple primary electron beams 20.

When the multiple primary electron beams 20 are incident on the electromagnetic lens 207 (objective lens), the electromagnetic lens 207 focuses the multiple primary electron beams 20 onto the substrate 101. In other words, the electromagnetic lens 207 illuminates the substrate 101 with the multiple primary electron beams 20. In this way, the primary electron optical system 151 applies the multiple primary electron beams 20 to the substrate 101.

The multiple primary electron beams 20 having been focused on the substrate 101 (target object) by the objective lens 207 are collectively deflected by the main deflector 208 and the sub deflector 209 to illuminate respective beam irradiation positions on the substrate 101. This is how the primary electron optical system 151 irradiates the substrate 101 with the multiple primary electron beams 20.

When desired positions on the substrate 101 are irradiated with the multiple primary electron beams 20, a flux of secondary electrons (multiple secondary electron beams 300) including reflected electrons is emitted from the substrate 101 because of being irradiated with the multiple primary electron beams 20. Specifically, secondary electron beams each corresponding to each of the multiple primary electron beams 20 are emitted.

The multiple secondary electron beams 300 emitted from the substrate 101 travel to a plurality of two or more multipole lenses (the E×B multipole lenses 214 and 217) through the electromagnetic lens 207. In the case of FIG. 1, they travel, after passing through the E×B multipole lens 217, to the E×B multipole lens 214.

The E×B multipole lens 214, which is arranged at a position being farthest from the electromagnetic lens 207 in a plurality of multipole lenses, separates the multiple secondary electron beams 300 from the trajectory of the multiple primary electron beams 20. In the plurality of multipole lenses arranged on the common trajectory of the first and second trajectories, the E×B multipole lens 214 is located at the most downstream side of the secondary electron beam trajectory.

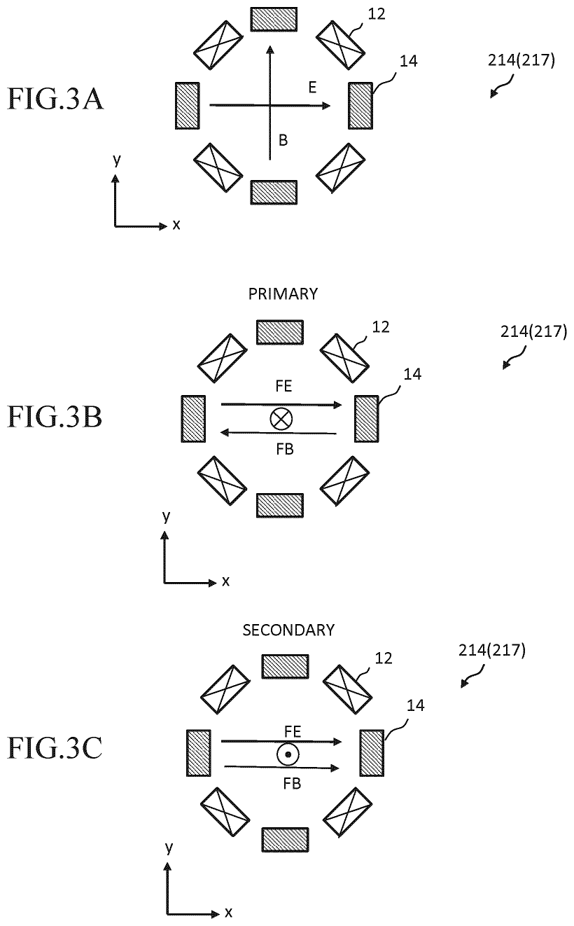

FIGS. 3A to 3C are diagrams for explaining a configuration and a deflection action of an E×B multipole lens according to the first embodiment. In FIGS. 3A to 3C, each of the E×B multipole lenses 214 and 217 includes at least four magnetic poles 12 each having a coil (electromagnetic deflection coils), and at least four electrodes 14 (electrostatic deflection electrodes). There are shown in FIGS. 3A to 3C a plurality of magnetic poles 12 whose phases are mutually shifted by 90°, and a plurality of electrodes 14 whose phases are also mutually shifted by 90°. Further, the plurality of magnetic poles 12 and the plurality of electrodes 14 are alternately arranged with shifted phases by 45°. The arranging method is not limited to this. The plurality of magnetic poles 12 and the plurality of electrodes 14 may be overlapped with each other at the same phases. A separation action is generated by deflecting the multiple secondary electron beams 300 by the E×B multipole lens 214 which is arranged at a position being the farther from the electromagnetic lens 207 of the E×B multipole lenses 214 and 217. In the E×B multipole lens 214, a directive magnetic field is generated by the plurality of magnetic poles 12, and, a directive electric field is generated by the plurality of electrodes 14. Specifically, as shown in FIG. 3A, the E×B multipole lens 214 generates an electric field E and a magnetic field B to be orthogonal to each other in a plane perpendicular to the traveling direction of the center beam (i.e., trajectory central axis) of the multiple primary electron beams 20. The electric field exerts a force in a fixed direction regardless of the traveling direction of electrons. By contrast, the magnetic field exerts a force according to Fleming's left-hand rule. Therefore, the direction of the force acting on (applied to) electrons can be changed depending on the entering (or “traveling”) direction of electrons. As shown in FIG. 3B, with respect to the multiple primary electron beams 20 entering the E×B multipole lens 214 from above, since a force FE due to the electric field and a force FB due to the magnetic field cancel each other out, the multiple primary electron beams 20 travel straight downward. By contrast, as shown in FIG. 3C, with respect to the multiple secondary electron beams 300 entering the E×B multipole lens 214 from below, since both the force FE due to the electric field and the force FB due to the magnetic field are exerted in the same direction, the beams 300 are bent obliquely upward by being deflected in a predetermined direction, and separated from the trajectory of the multiple primary electron beams 20.

The multiple secondary electron beams 300 having been bent obliquely upward and separated from the multiple primary electron beams 20 are led to the multi-detector 222 by the secondary electron optical system 152. Specifically, the multiple secondary electron beams 300 separated from the multiple primary electron beams 20 are further bent by being deflected by the deflector 218, and travel to the electromagnetic lens 224. Then, the multiple secondary electron beams 300 are projected on the multi-detector 222 while being refracted in a converging direction by the electromagnetic lens 224, at the position away from the trajectory of the multiple primary electron beams 20. The multi-detector 222 (multiple secondary electron beam detector) detects the multiple secondary electron beams 300 having been separated from the trajectory of the multiple primary electron beams 20. In other words, the multi-detector 222 detects the refracted and projected multiple secondary electron beams 300. The multi-detector 222 includes a plurality of detection elements (e.g., diode type two-dimensional sensor (not shown)). At the detection surface of the multi-detector 222, each beam of the multiple primary electron beams 20 collides with a detection element corresponding to each beam of the multiple secondary electron beams 300, and generates electrons, and secondary electron image data for each pixel. An intensity signal detected by the multi-detector 222 is output to the detection circuit 106.

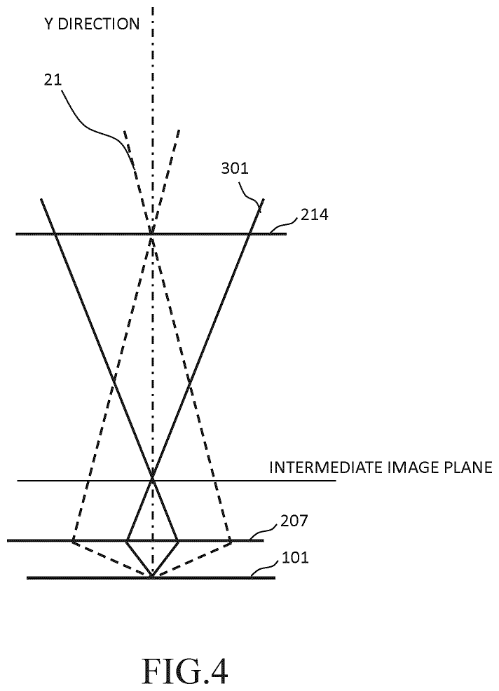

FIG. 4 is a diagram showing an example of trajectories of multiple primary electron beams and multiple secondary electron beams according to a comparative example of the first embodiment. This comparative example shows the case where the E×B multipole lens 214 being one stage is arranged. The multiple primary electron beams 20 spread after passing through the E×B multipole lens 214 which is arranged at a position conjugate to the image plane of the multiple primary electron beams 20, and their trajectory is bent in the converging direction by the magnetic lens 207 (objective lens) to be imaged on the surface of the substrate 101. FIG. 4 shows the trajectory of a center primary electron beam 21 in the multiple primary electron beams 20. Then, the multiple secondary electron beams 300 are emitted from the substrate 101 because of being irradiated with the multiple primary electron beams 20. The energy at the emission of a center secondary electron beam 301, corresponding to the center primary electron beam 21, in the multiple secondary electron beams 300 is smaller than the incident energy on the substrate 101 of the center primary electron beam 21. Therefore, under the conditions that the primary electron beam is imaged on the surface of the E×B multipole lens 214 and the objective lens focuses the multiple primary electron beams 20 on the substrate 101, as shown in FIG. 4, an intermediate image plane (image forming point) of the center secondary electron beam 301 is formed at the position before the center secondary electron beam 301 reaches the E×B multipole lens 214 by that the trajectory of the center secondary electron beam 301 is bent in the converging direction by the magnetic lens 207. Then, the center secondary electron beam 301 travels, while spreading, to the E×B multipole lens 214. According to the comparative example, the center secondary electron beam 301 travels, while further spreading, to the deflector 218. Since the beam diameter of each secondary electron beam is large in the E×B multipole lens 214, aberration generated in each secondary electron beam which has been deflected to be separated becomes large. As a result, the multiple secondary electron beams 300 detected by the multi-detector 222 may be overlapped with each other.

According to the first embodiment, a plurality of two or more multipole lenses are arranged to exert a lens effect (lens action) on the multiple secondary electron beams 300. As the plurality of multipole lenses, the E×B multipole lenses 214 and 217 are used.

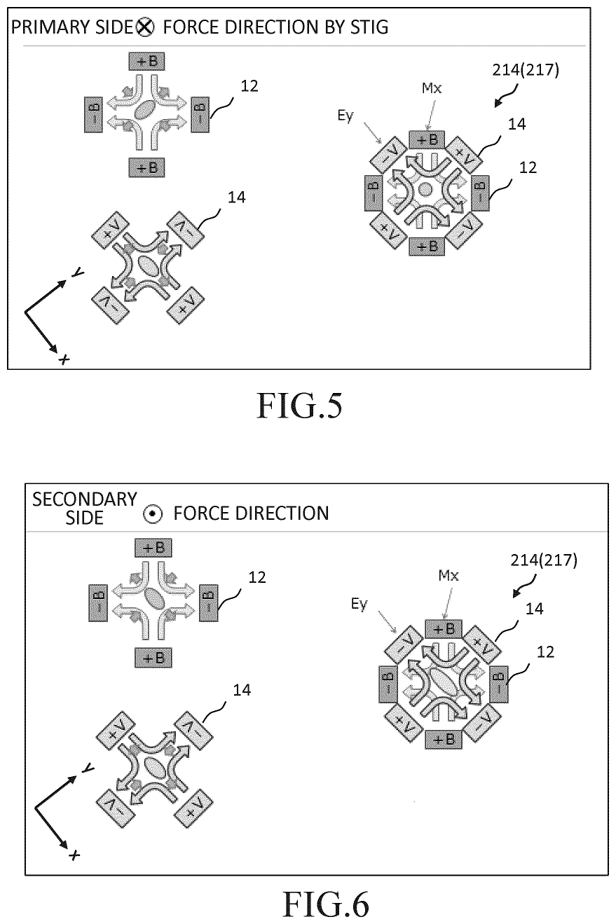

FIG. 5 is a diagram for explaining a lens effect of an E×B multipole lens on multiple primary electron beams according to the first embodiment. In FIG. 5, as described above, each of the E×B multipole lenses 214 and 217 includes the four magnetic poles 12 whose phases are mutually shifted by 90° and the four electrodes 14 whose phases are also mutually shifted by 90°. A magnetic quadrupole field is formed by the four magnetic poles 12. An electric quadrupole field is formed by the four electrodes 14. In the quadrupole field of the first embodiment, a convergence action is generated in one of two directions which are perpendicular to the trajectory central axis of an electron beam, and a divergence action is generated in the other of the two directions. Thus, opposite lens actions can be exerted, on a passing electron beam, in two directions being orthogonal to each other such as x and y directions. In FIG. 5, the directions of the electric field and the magnetic field are perpendicular to each other. By this, in the case of FIG. 5, a divergence action in the y direction and a convergence action in the x direction are generated for the multiple primary electron beams 20 by the magnetic quadrupole field. On the other hand, a divergence action in the x direction and a convergence action in the y direction are generated by the electric quadrupole field. Thus, in FIG. 5, by making the directions of the electric field and the magnetic field perpendicular to each other, forces exerted on the multiple primary electron beams 20 by the electric field and the magnetic field can be cancelled out each other. Therefore, the multiple primary electron beams 20 can pass through without being exerted by the lens action. The magnitude of the force by the electric field and that by the magnetic field are adjusted to be the same as each other. Further, for example, by providing eight electrodes and eight magnetic poles, the multipole lens can generate a quadrupole field in any desired direction.

FIG. 6 is a diagram for explaining a lens effect of an E×B multipole lens on multiple secondary electron beams according to the first embodiment. As described above, in the quadrupole field of the first embodiment, a convergence action is generated in one of two directions which are perpendicular to the trajectory central axis of an electron beam, and a divergence action is generated in the other of the two directions. As described referring to FIG. 5, the directions of the electric field and the magnetic field are made to be perpendicular to each other. By this, in the case of FIG. 6, a divergence action in the x direction and a convergence action in the y direction are generated for the multiple secondary electron beams 300 by the magnetic quadrupole field. Further, a divergence action in the x direction and a convergence action in the y direction are generated by the electric quadrupole field. Thus, in FIG. 6, by making the directions of the electric field and the magnetic field perpendicular to each other, forces exerted on the multiple secondary electron beams 300 by the electric field and the magnetic field can be generated in the same direction. Therefore, the lens effect by the magnetic quadrupole field and the lens effect by the electric quadrupole field can be in the same direction.

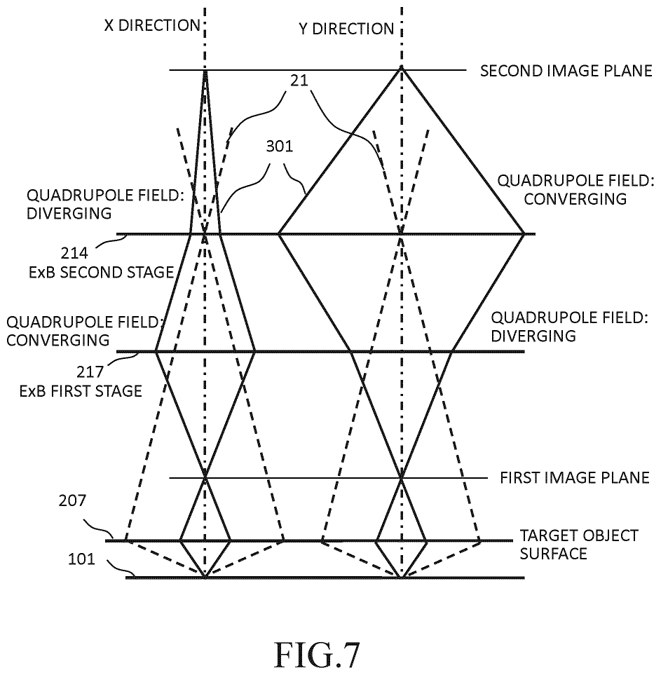

FIG. 7 is a diagram showing an example of trajectories of multiple primary electron beams and multiple secondary electron beams in a quadrupole field according to the first embodiment. In FIG. 7, both the x and y direction widths of the multiple primary electron beams 20 (dotted line) spread after passing through the E×B multipole lens 214 arranged at a position conjugate to the image plane of the multiple primary electron beams 20. Then, after passing through the E×B multipole lens 217, the trajectory of the multiple primary electron beams 20 is bent in the converging direction along both the x and y directions by the magnetic lens 207 (objective lens) to be imaged on the surface of the substrate 101. FIG. 7 shows the trajectory of the center primary electron beam 21 in the multiple primary electron beams 20. The multiple secondary electron beams 300 are emitted from the substrate 101 because of being irradiated with the multiple primary electron beams 20. As described above, the energy at the emission of the center secondary electron beam 301 is smaller than the incident energy on the substrate 101 of the center primary electron beam 21. Therefore, under the conditions that the primary electron beam is imaged on the surface of the E×B multipole lens 214 and the objective lens focuses the multiple primary electron beams 20 on the substrate 101, similarly to FIG. 4, an intermediate image plane (image forming point) (the first image plane) of the center secondary electron beam 301 is formed at the position before the center secondary electron beam 301 reaches the E×B multipole lens 217 by that the trajectory of the center secondary electron beam 301 is bent in the converging direction by the magnetic lens 207.

Then, the center secondary electron beam 301 travels, while spreading, to the E×B multipole lens 217.

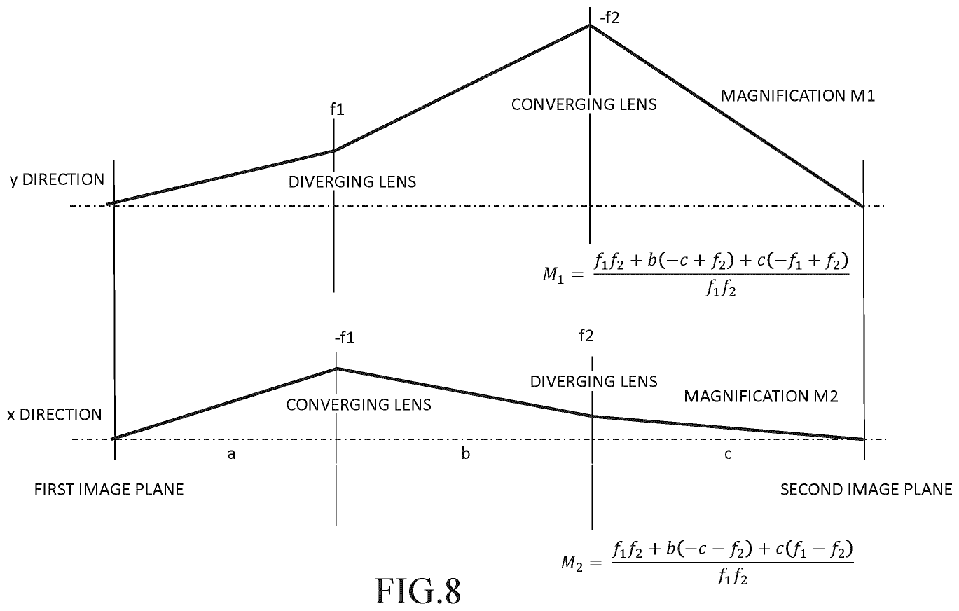

FIG. 8 is a diagram for explaining an effect of a two-stage quadrupole lens according to the first embodiment. In FIG. 8, a plurality of multipole lenses exert, on the multiple secondary electron beams 300, one of lens effects of a divergence effect and a convergence effect in the x direction (the first direction) perpendicular to the trajectory central axis of the multiple secondary electron beams 300. Further, they exert, on the multiple secondary electron beams 300, the other of the lens effects of the divergence effect and the convergence effect in the y direction (the second direction) perpendicular to the trajectory central axis of the multiple secondary electron beams 300. In the two-stage quadrupole lens shown in FIG. 8, the lens effects generated by the first and second stage quadrupole lenses are opposite.

In the examples of FIGS. 7 and 8, the E×B multipole lens 217 exerts a converging effect in the x direction on the multiple secondary electron beams 300. In other words, it acts as a converging lens. Further, the E×B multipole lens 217 exerts a diverging effect in the y direction on the multiple secondary electron beams 300. In other words, it acts as a diverging lens. Thus, the E×B multipole lens 217 bends the trajectory of the multiple secondary electron beams 300 in the converging direction along the x direction, and bends it in the diverging direction along the y direction. Then, the multiple secondary electron beams 300 travel to the E×B multipole lens 214.

By contrast, the E×B multipole lens 214 generates a lens effect opposite to that of the E×B multipole lens 217. Specifically, the E×B multipole lens 214 exerts a diverging effect in the x direction on the multiple secondary electron beams 300. In other words, it acts as a diverging lens. Further, the E×B multipole lens 214 exerts a converging effect in the y direction on the multiple secondary electron beams 300. In other words, it acts as a converging lens. Thus, the E×B multipole lens 214 bends the trajectory in the diverging direction along the x direction, and bends it in the converging direction along the y direction. Then, the multiple secondary electron beams 300 are imaged on the intermediate image plane (the second image plane).

Regarding the two-stage quadrupole lens, generally, the magnification in the direction of proceeding from convergence to divergence is larger than that in the direction of proceeding from divergence to convergence at the intermediate image plane (the second image plane). FIG. 8 shows the distance “a” from the first image plane to the lens center of the E×B multipole lens 217 (the first stage), the distance “b” from the lens center of the E×B multipole lens 217 (the first stage) to the lens center of the E×B multipole lens 214 (the second stage), and the distance “c” from the lens center of the E×B multipole lens 214 (the second stage) to the second image plane. Further, it shows a focal distance f₁ of the diverging lens of the E×B multipole lens 217 (the first stage), and a focal distance −f₁ of the converging lens of the E×B multipole lens 217 (the first stage). Also, it shows a focal distance f₂ of the diverging lens of the E×B multipole lens 214 (the second stage), and the focal distance −f₂ of the converging lens of the E×B multipole lens 214 (the second stage). Furthermore, it shows a magnification M₁ in the y direction from the lens center of the E×B multipole lens 214 (the second stage) to the second image plane, and a magnification M₂ in the x direction from the lens center of the E×B multipole lens 214 (the second stage) to the second image plane.

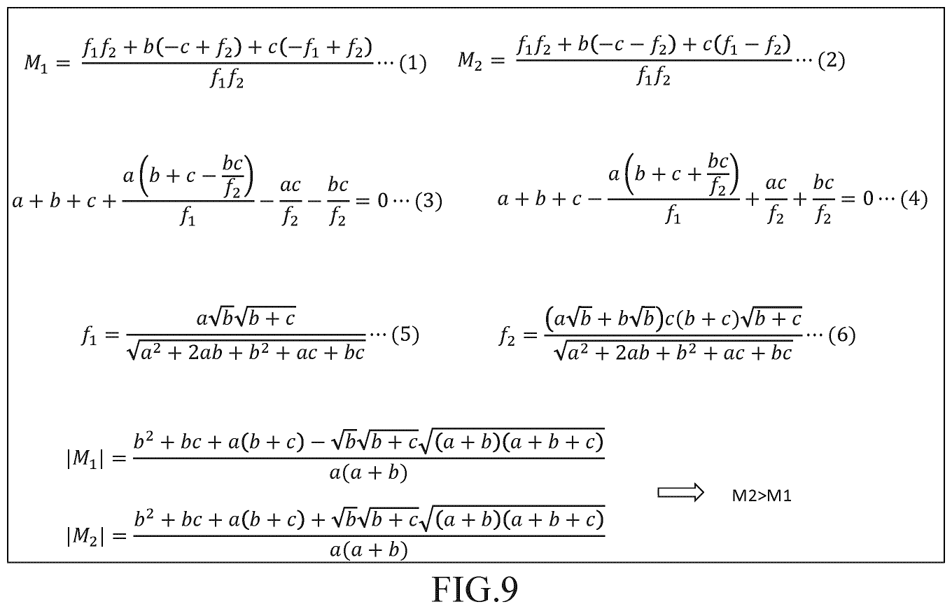

FIG. 9 shows magnification equations based on a two-stage quadrupole field according to the first embodiment. FIG. 9 shows magnification equations in the state of FIG. 8. In FIG. 9, the y-direction magnification M₁ can be defined by the equation (1), the x-direction magnification M₂ can be defined by the equation (2), a y-direction image forming condition (conjugate condition) can be defined by the equation (3), and an x-direction image forming condition (conjugate condition) can be defined by the equation (4). When solving with respect to focal distances f₁ and f₂ by the equations (3) and (4), the focal distance f₁ can be defined by the equation (5), and the focal distance f₂ can be defined by the equation (6). When substituting the equations (5) and (6) into the equations (1) and (2), the absolute value of the y-direction magnification M₁ and the absolute value of the x-direction magnification M₂ can be obtained. By comparing the absolute value of the y-direction magnification M₁ with that of the x-direction magnification M₂, it turns out that the x-direction magnification M₂ is larger than the y-direction magnification M₁.

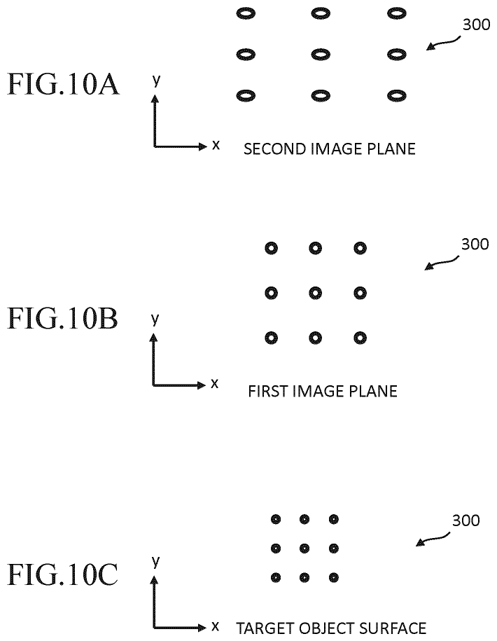

FIGS. 10A to 10C are illustrations showing examples of the state of multiple secondary electron beams at image planes of a two-stage quadrupole field according to the first embodiment. The multiple secondary electron beams 300 at the surface of the target object shown in FIG. 10C have no magnification difference with respect to the x and y directions at the first image plane by the lens effect of the electromagnetic lens 207 (objective lens) as shown in FIG. 10B, but in contrast to this, as shown in FIG. 10A, they have elliptical shapes extending in the x direction, at the second image plane due to the lens effect of the E×B multipole lens 214 being the second stage.

As described above, in order to detect the multiple secondary electron beams 300, it is necessary to separate the multiple secondary electron beams 300 from the multiple primary electron beams 20. According to the first embodiment, by one of a plurality of multipole lenses, the multiple secondary electron beams 300 are separated from the trajectory of the multiple primary electron beams 20. In other words, the multiple secondary electron beams 300 are separated from the trajectory of the multiple primary electron beams 20 by one multipole lens at a position being farthest from the substrate 101 in the plurality of multipole lenses arranged on the common trajectory of the primary electron beam and the secondary electron beam. Therefore, in the example of FIG. 1, the multiple secondary electron beams 300 are separated from the trajectory of the multiple primary electron beams 20 by the E×B multipole lens 214. In order to separate the multiple secondary electron beams 300, a deflection field for deflecting the multiple secondary electron beams 300 is added to (or “combined with”) the quadrupole field in the E×B multipole lens 214.

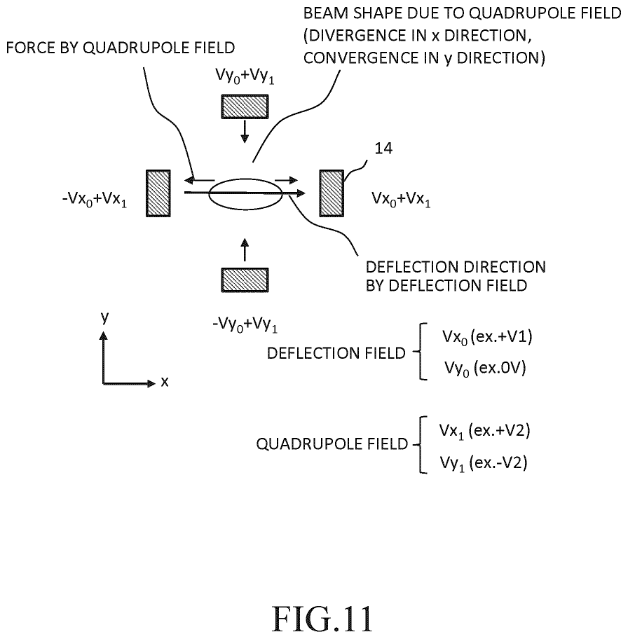

FIG. 11 is an illustration showing an example of a force direction by a quadrupole field and a deflection direction by a deflection field according to the first embodiment. In FIG. 11, four electrodes 14 are used for explanation, and an action of four magnetic poles 12 is not illustrated. Vx₀ denotes an x-direction electrode potential and Vy₀ denotes a y-direction electrode potential which form the deflection field. Vx₁ denotes an x-direction electrode potential and Vy₁ denotes a y-direction electrode potential which form the quadrupole field.

In the quadrupole field, as described above, electric potentials of the same sign are applied to counter electrodes. In the case of FIG. 11, +Vx₁ is applied to right and left electrodes individually. +Vy₁ is applied to upper and lower electrodes individually. For example, when Vx₁=+V2 and Vy₁=−V2, a lens effect can be generated to diverge in the x direction and converge in the y direction.

In the deflection field, as described with reference to FIGS. 3A to 3C, electric potentials of the same magnitude and reversed signs are applied to counter electrodes. In the case of FIG. 11, +Vy₀ is determined as the potential of the upper electrode, −Vy₀ is as the potential of the counter lower electrode, +Vx₀ is as the potential of the right electrode, and −Vx₀ is as the potential of the counter left electrode. For example, when Vx₀=+V1 and Vy₀=0, a force FE by the electric field, which deflects the multiple secondary electron beams 300 in the x direction, can be generated.

In the first embodiment, the quadrupole field and the deflection field are added (or “combined”) with respect to the E×B multipole lens 214. In this process, according to the first embodiment, the multiple secondary electron beams 300 are deflected in the direction of proceeding from convergence to divergence in the quadrupole field.

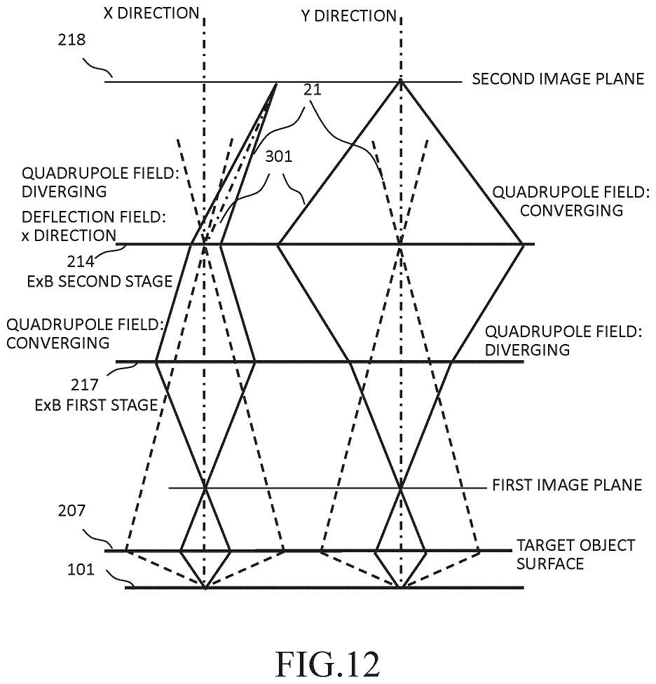

FIG. 12 is an illustration showing examples of the trajectories of multiple secondary electron beams and multiple primary electron beams in the state where a deflection field is combined with a two-stage quadrupole field according to the first embodiment. The trajectory of the multiple primary electron beams 20 (dotted line) is the same as that of FIG. 7. FIG. 12 shows the trajectory of the center primary electron beam 21 in the multiple primary electron beams 20. The trajectory of the multiple secondary electron beams 300, up to the E×B multipole lens 214, is the same as that of FIG. 7.

In the case of FIG. 12, the multiple secondary electron beams 300 are deflected in the x direction by the deflection field of the E×B multipole lens 214. By this, the multiple secondary electron beams 300 are separated from the multiple primary electron beams 20, thereby travelling toward the deflector 218. In the quadrupole field of the E×B multipole lens 214, a lens effect opposite to that of the E×B multipole lens 217 is generated. Specifically, the E×B multipole lens 214 exerts an x-direction divergence effect on the multiple secondary electron beams 300. In other words, it acts as a diverging lens. Then, the E×B multipole lens 214 exerts a y-direction convergence effect on the multiple secondary electron beams 300. In other words, it acts as a converging lens. Therefore, by the E×B multipole lens 214, the trajectory is bent in the diverging direction along the x direction, and it is further bent in the converging direction along the y direction, thereby forming an image on the intermediate image plane (the second image plane).

According to the first embodiment, the multiple secondary electron beams 300 are separated, by the E×B multipole lens 214, in one of the x and y directions which is a direction of a divergence effect. With respect to the x direction of proceeding from convergence to divergence in the quadrupole field, the beam diameter on the E×B multipole lens 214 is small. Therefore, the multiple secondary electron beams 300 are deflected in the x direction. Thereby, aberration which occurs due to the deflection by the E×B multipole lens 214 can be decreased. Accordingly, in the multi-detector 222, overlapping of the beams can be prevented and a secondary electron beam can be detected individually.

Further, by adjusting the intermediate image plane (the second image plane) to be at the center position of the deflector 218, aberration generated due to deflection by the deflector 218 can be decreased.

The magnification of the multiple secondary electron beams 300 changes according to deflection by the E×B multipole lens 214. With respect to the ratio between an x-direction magnification Mx and a y-direction magnification My in the case of x-direction deflection, it is Mx/My<1. According to the first embodiment, the multiple secondary electron beams 300 are deflected in the x direction of proceeding from convergence to divergence in the quadrupole field. Therefore, the x-direction magnification which has increased in the quadrupole field can be decreased in the deflection field. Thus, the magnification difference between the x and y directions can be improved.

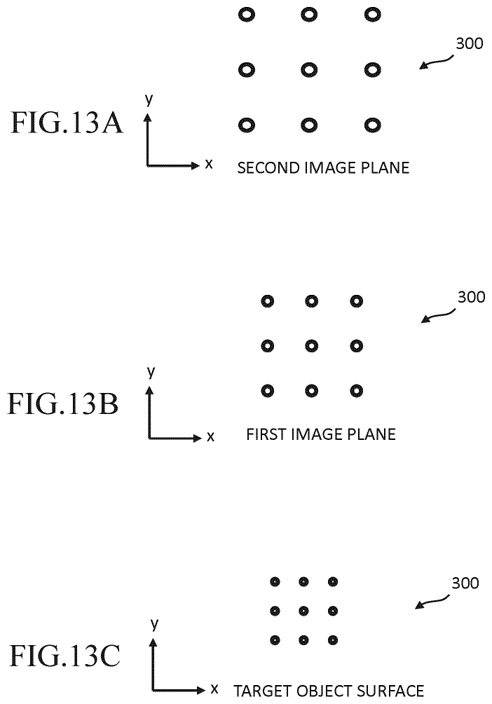

FIGS. 13A to 13C are illustrations showing examples of the state of multiple secondary electron beams at image planes of a field where a deflection field is combined with a two-stage quadrupole field according to the first embodiment. The multiple secondary electron beams 300 at the surface of the target object shown in FIG. 13C have no magnification difference with respect to the x and y directions at the first image plane by the lens effect of the electromagnetic lens 207 (objective lens) as shown in FIG. 13B. In contrast to this, at the second image plane due to the lens effect of the E×B multipole lens 214 being the second stage, the magnification difference between the x and y directions becomes smaller than that of FIG. 10A by deflection as shown in FIG. 13A.

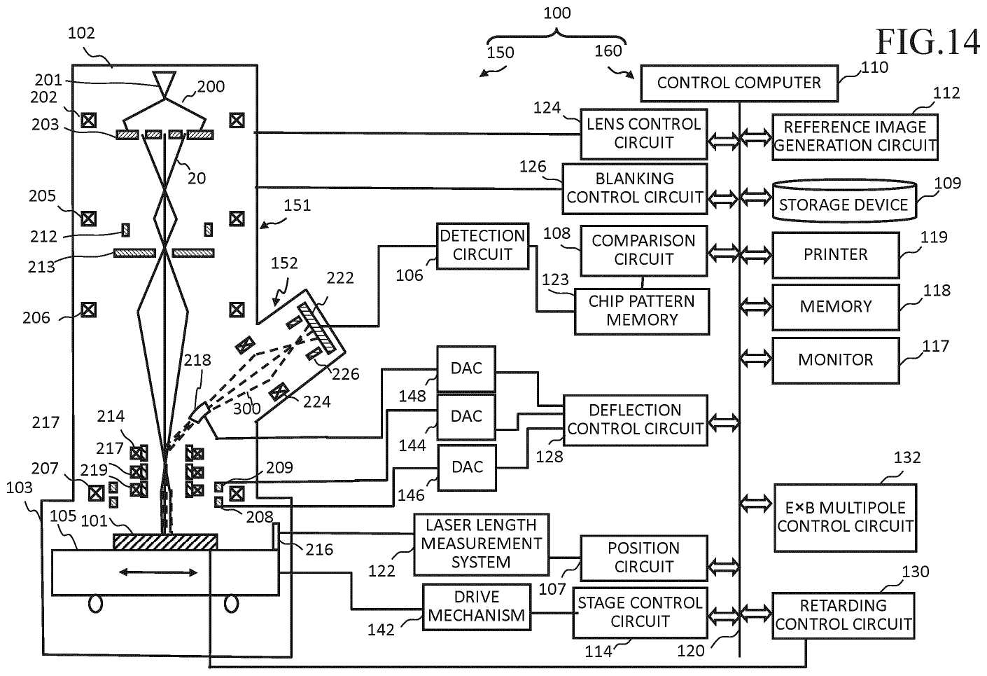

FIG. 14 is a configuration diagram of a pattern inspection apparatus according to a first modified example of the first embodiment. In the case of FIG. 14, as a plurality of two or more multipole lenses, there is arranged a three-stage multipole lens composed of the first multipole lens, the second multipole lens, and the third multipole lens. As the three-stage multipole lens, E×B multipole lenses 214, 217, and 219 are arranged at positions common to the trajectory of the multiple primary electron beams 20 and that of the multiple secondary electron beams 300. In the case of FIG. 14, the E×B multipole lenses 214, 217, and 219 are located between the electromagnetic lenses 206 and 207. The multiple secondary electron beams 300 are separated from the trajectory of the multiple primary electron beams 20 by one multipole lens at a position being farthest from the substrate in the E×B multipole lenses 214, 217, and 219.

In also the case of using the E×B multipole lenses 214, 217, and 219 forming three stages, forces due to the electric field and the magnetic field can be cancelled out each other with respect to the travelling direction of the multiple primary electron beams 20 by forming the electric field and the magnetic field to be perpendicular to each other and equalizing the forces due to the electric field and the magnetic field. Therefore, it becomes possible to make the multiple primary electron beams 20 proceed straightly.

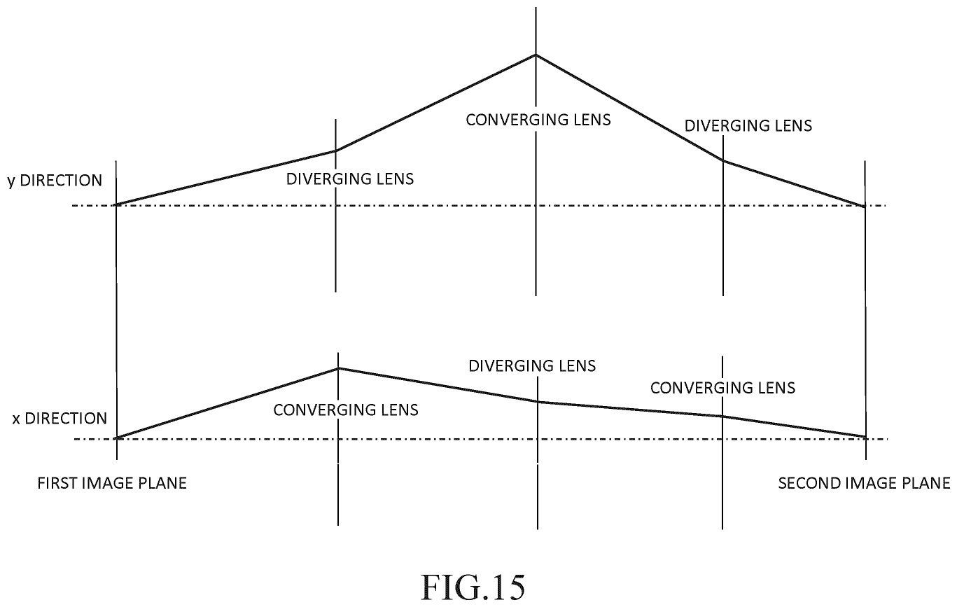

FIG. 15 is a diagram showing an example of a trajectory of multiple secondary electron beams in a quadrupole field according to the first modified example of the first embodiment. The trajectory of the multiple primary electron beams 20 is the same as that of FIG. 7. Under the conditions that the primary electron beam is imaged on the surface of the E×B multipole lens 214 and the objective lens focuses the multiple primary electron beams 20 on the substrate 101, similarly to FIG. 4, an intermediate image plane (image forming point) (the first image plane) of the center secondary electron beam 301 is formed at the position before the center secondary electron beam 301 reaches the E×B multipole lens 217 by that the trajectory of the center secondary electron beam 301 is bent in the converging direction by the magnetic lens 207.

Then, the center secondary electron beam 301 travels, while spreading, to the E×B multipole lens 219 (first stage).

In the example of FIG. 15, the E×B multipole lens 219 (first stage) exerts a converging effect in the x direction on the multiple secondary electron beams 300. In other words, it acts as a converging lens. Further, the E×B multipole lens 219 exerts a diverging effect in the y direction on the multiple secondary electron beams 300. In other words, it acts as a diverging lens. Thus, the E×B multipole lens 219 bends the trajectory in the converging direction along the x direction, and bends it in the diverging direction along the y direction. Then, the multiple secondary electron beams 300 travel to the E×B multipole lens 217.

The E×B multipole lens 217 (second stage) generates a lens effect opposite to that of the E×B multipole lens 219. Specifically, the E×B multipole lens 217 exerts a diverging effect in the x direction on the multiple secondary electron beams 300. In other words, it acts as a diverging lens. Further, the E×B multipole lens 217 exerts a converging effect in the y direction on the multiple secondary electron beams 300. In other words, it acts as a converging lens. Thus, the E×B multipole lens 217 bends the trajectory in the diverging direction along the x direction, and bends it in the converging direction along the y direction. Then, the multiple secondary electron beams 300 travel to the E×B multipole lens 214.

The E×B multipole lens 214 (third stage) generates a lens effect opposite to that of the E×B multipole lens 217. Specifically, the E×B multipole lens 214 exerts a diverging effect in the x direction on the multiple secondary electron beams 300. In other words, it acts as a diverging lens. Further, the E×B multipole lens 214 exerts a converging effect in the y direction on the multiple secondary electron beams 300. In other words, it acts as a converging lens. Thus, the E×B multipole lens 214 bends the trajectory in the converging direction along the x direction, and bends it in the diverging direction along the y direction. Then, the multiple secondary electron beams 300 are imaged on the intermediate image plane (the second image plane).

As described above, due to the E×B multipole lens 219 (the first stage) and the E×B multipole lens 217 (the second stage), the magnification in the x direction of proceeding from convergence to divergence is larger than that in the y direction of proceeding from divergence to convergence at the intermediate image plane (the second image plane). According to the first modified example of the first embodiment, the lens effect is reversed by the E×B multipole lens 214 (the third stage), so that it proceeds in order of convergence, divergence, and convergence in the x direction. By this, namely, by performing convergence again, the magnification that has become larger due to the order of from convergence to divergence can be closer in size to the magnification in the y direction. Further, divergence, convergence, and divergence are performed in this order in the y direction. By this, namely, by performing divergence again, the magnification that has become smaller due to the order of from divergence to convergence can be closer in size to the magnification in the x direction. Thus, the magnification difference generated with respect to the x and y directions can be improved.

In the case of the first modified example of the first embodiment, the deflection direction using the E×B multipole lens 214 may be the x direction, or the y direction. Since the beam diameter on the E×B multipole lens 214 being the third stage can be decreased not only in the x direction but also in the y direction, aberration due to deflection can be decreased in either direction. Further, since the magnification difference can be decreased, it is acceptable to perform deflection in either direction.

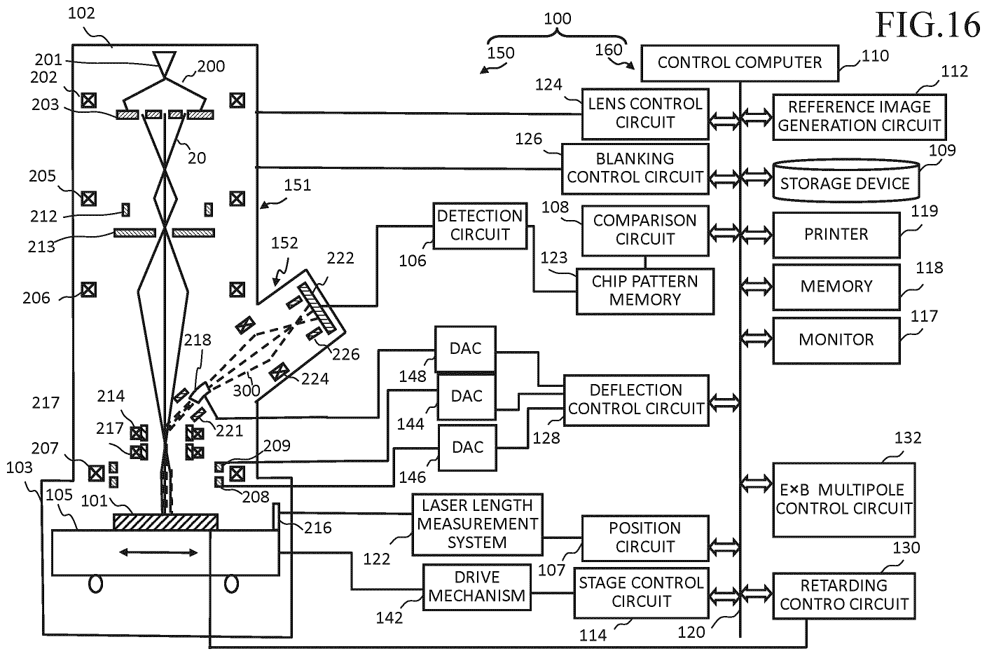

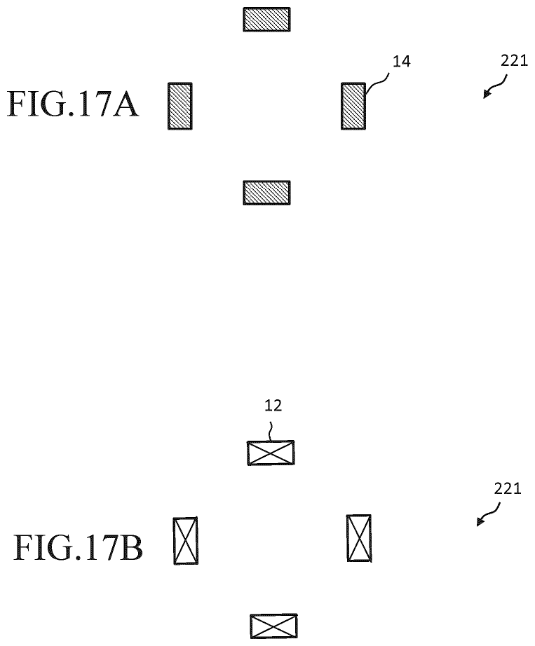

FIG. 16 is a configuration diagram of a pattern inspection apparatus according to a second modified example of the first embodiment. In the case of FIG. 16, as a plurality of multipole lenses, there is arranged a three-stage multipole lens composed of the first multipole lens, the second multipole lens, and the third multipole lens. In the three-stage multipole lens, the E×B multipole lenses 214 and 217 are arranged, similarly to FIG. 1, at positions common to the trajectory of the multiple primary electron beams 20 and that of the multiple secondary electron beams 300. Then, a multipole lens 221 is arranged in the middle of the trajectory of the multiple secondary electron beams 300 separated from the trajectory of the multiple primary electron beams 20. In the case of FIG. 16, the multipole lens 221 is arranged between the E×B multipole lens 214 and the deflector 218. The multiple secondary electron beams 300 are separated from the trajectory of the multiple primary electron beams 20 by the E×B multipole lens 214 at a position being the farther from the substrate of the E×B multipole lenses 214 and 217.

FIGS. 17A and 17B are illustrations showing examples of the third multipole lens according to the second modified example of the first embodiment. In the case of arranging a multipole lens at a position common to the trajectory of the multiple primary electron beams 20 and that of the multiple secondary electron beams 300, it is necessary to use an E×B multipole lens in order to make the multiple primary electron beams 20 proceed straightly. However, in the case of arranging a multipole lens at a position on the trajectory of the multiple secondary electron beams 300 separated from the multiple primary electron beams 20, there is no necessity to consider the influence on the multiple primary electron beams 20. Therefore, it is sufficient to use one of the magnetic quadrupole field and the electric quadrupole field. Accordingly, the multipole lens 221 may include at least either of a plurality of four or more electrodes and a plurality of four or more magnetic poles. For example, the multipole lens 221 may be composed of four electrodes 14 as shown in FIG. 17A, or composed of four magnetic poles 12 as shown in FIG. 17B.

An example of a trajectory of multiple secondary electron beams in a quadrupole field according to the second modified example of the first embodiment may be the same as that of FIG. 15. According to the second modified example of the first embodiment, the lens effect is reversed by the multipole lens 221 (the third stage), so that it proceeds in order of convergence, divergence, and convergence in the x direction. By this, namely, by performing convergence again, the magnification that has become larger due to the order of from convergence to divergence can be closer in size to the magnification in the y direction. Further, divergence, convergence, and divergence are performed in this order in the y direction. By this, namely, by performing divergence again, the magnification that has become smaller due to the order of from divergence to convergence can be closer in size to the magnification in the x direction. Thus, similarly to the first modified example, the magnification difference generated with respect to the x and y directions can be improved in the second modified example of the first embodiment.

In the case of the second modified example of the first embodiment, similarly to the first modified example, the deflection direction using the E×B multipole lens 214 may be the x direction, or the y direction. Since the beam diameter on the multipole lens 221 being the third stage can be decreased not only in the x direction but also in the y direction, aberration due to deflection can be decreased in either direction. Further, since the magnification difference can be decreased, it is acceptable to perform deflection in either direction.

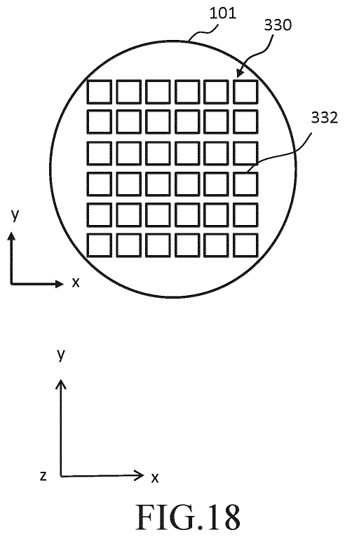

FIG. 18 is an illustration showing an example of a plurality of chip regions formed on a semiconductor substrate, according to the first embodiment. In FIG. 18, a plurality of chips (wafer die) 332 are formed in a two-dimensional array in an inspection region 330 of the semiconductor substrate (wafer) 101. A mask pattern for one chip formed on an exposure mask substrate is reduced to, for example, ¼, and exposed/transferred onto each chip 332 by an exposure device (stepper) (not shown).

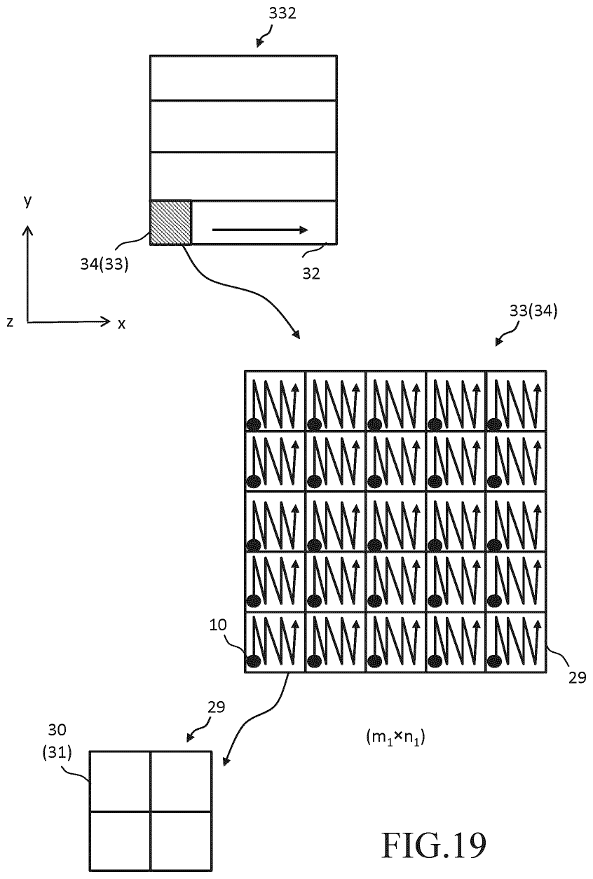

FIG. 19 is an illustration describing image acquiring processing according to the first embodiment. As shown in FIG. 19, the region of each chip 332 is divided, for example, in the y direction into a plurality of stripe regions 32 by a predetermined width. The scanning operation by the image acquisition mechanism 150 is carried out for each stripe region 32, for example. The operation of scanning the stripe region 32 advances relatively in the x direction while the stage 105 is moved in the −x direction, for example. Each stripe region 32 is divided in the longitudinal direction into a plurality of rectangular (including square) regions 33. Beam application to a target rectangular region 33 is achieved by collectively deflecting all the multiple primary electron beams 20 by the deflector 208.

FIG. 1 shows the case of multiple primary electron beams 20 of 5 rows by 5 columns. The size of an irradiation region 34 that can be irradiated by one irradiation with the multiple primary electron beams 20 is defined by (the x-direction size obtained by multiplying the x-direction beam pitch of the multiple primary electron beams 20 on the substrate 101 by the number of x-direction beams)×(the y-direction size obtained by multiplying the y-direction beam pitch of the multiple primary electron beams 20 on the substrate 101 by the number of y-direction beams). The irradiation region 34 serves as a field of view of the multiple primary electron beams 20. A sub-irradiation region 29, which is surrounded by the x-direction beam pitch and the y-direction beam pitch and in which a primary electron beam 10 concerned itself is located, is irradiated and scanned by each primary electron beam 10 of the multiple primary electron beams 20. Each primary electron beam 10 is associated with any one of the sub-irradiation regions 29 which are different from each other. At the time of each shot, each primary electron beam 10 is applied to the same position in the associated sub-irradiation region 29. The surface of the substrate 101 where a pattern has been formed is scanned by the multiple primary electron beams 20 collectively deflected by the sub deflector 209 (first deflector). In other words, the primary electron beam 10 is moved in the sub-irradiation region 29 by collective deflection of all of the multiple primary electron beams 20 by the sub deflector 209. By repeating this operation, one sub-irradiation region 29 is irradiated in order with one primary electron beam 10.

Preferably, the width of each stripe region 32 is set to be the same as the size in the y direction of the irradiation region 34, or to be the size reduced by the width of the scanning margin. In the cases of FIGS. 13A to 13C, the irradiation region 34 and the rectangular region 33 are of the same size. However, it is not limited thereto. The irradiation region 34 may be smaller than the rectangular region 33, or larger than it. Using each primary electron beam 10 of the multiple primary electron beams 20, the sub-irradiation region 29 in which the primary electron beam 10 concerned itself is located is irradiated and scanned by the primary electron beam 10 concerned. Then, when scanning of one sub-irradiation region 29 is completed, the irradiation position is moved to an adjacent rectangular region 33 in the same stripe region 32 by collectively deflecting all the multiple primary electron beams 20 by the deflector 208. By repeating this operation, the stripe region 32 is irradiated in order. After completing scanning of one stripe region 32, the irradiation region 34 is moved to the next stripe region 32 by moving the stage 105 and/or by collectively deflecting all the multiple primary electron beams 20 by the deflector 208. As described above, by irradiation with each primary electron beam 10, the scanning operation per sub-irradiation region 29 and acquisition of a secondary electron image are performed. By combining these secondary electron images of respective sub-irradiation regions 29, a secondary electron image of the rectangular region 33, a secondary electron image of the stripe region 32, or a secondary electron image of the chip 332 is configured. When an image comparison is actually performed, the sub-irradiation region 29 in each rectangular region 33 is further divided into a plurality of frame regions 30, and then, a comparison is performed with respect to a frame image 31 being a measured image of each frame region 30. FIG. 19 shows the case of dividing the sub-irradiation region 29 which is scanned by one primary electron beam 10 into four frame regions 30 by halving it in the x and y directions, for example.

In the case of applying the multiple primary electron beams 20 to the substrate 101 while the stage 105 is continuously moving, the main deflector 208 executes a tracking operation by performing collective deflection so that the irradiation position of the multiple primary electron beams 20 may follow the movement of the stage 105. Therefore, the emission position of the multiple secondary electron beams 300 changes every second with respect to the trajectory central axis of the multiple primary electron beams 20. Similarly, in the case of scanning the sub-irradiation region 29, the emission position of each secondary electron beam changes every second inside the sub-irradiation region 29. For example, the deflector 226 collectively deflects the multiple secondary electron beams 300 so that each secondary electron beam whose emission position has changed may be applied to a corresponding detection region of the multi-detector 222. It is also preferable that an alignment coil or the like, in addition to the deflector 226, is arranged in the secondary electron optical system in order to correct the change of the emission position.

As described above, the image acquisition mechanism 150 proceeds with a scanning operation per stripe region 32. The multiple secondary electron beams 300 emitted from the substrate 101 because of being irradiated with the multiple primary electron beams 20 form an intermediate image plane (the second image plane) in the deflector 218 and are deflected by the deflector 218, and then, detected by the multi-detector 222 as described above. A reflected electron may be included in the detected multiple secondary electron beams 300. Alternatively, a reflected electron may diffuse during moving in the secondary electron optical system and therefore may not reach the multi-detector 222. Secondary electron images are acquired based on signals of the detected multiple secondary electron beams 300. Specifically, detected data (measured image data: secondary electron image data: inspection image data) on the secondary electron of each pixel in each sub-irradiation region 29, detected by the multi-detector 222, is output to the detection circuit 106 in order of measurement. In the detection circuit 106, the detected data in an analog form is converted into digital data by an A-D converter (not shown), and stored in the chip pattern memory 123. Then, acquired measured image data is transmitted to the comparison circuit 108, together with information on each position from the position circuit 107.

Meanwhile, the reference image generation circuit 112 generates, for each frame region 30, a reference image corresponding to the frame image 31, based on design data serving as a basis of a plurality of figure patterns formed on the substrate 101. Specifically, it operates as follows: First, design pattern data is read from the storage device 109 through the control computer 110, and each figure pattern defined by the read design pattern data is converted into image data of binary or multiple values.

As described above, basic figures defined by the design pattern data are, for example, rectangles (including squares) and triangles. For example, there is stored figure data defining the shape, size, position, and the like of each pattern figure by using information, such as coordinates (x,y) of the reference position of the figure, lengths of sides of the figure, and a figure code serving as an identifier for identifying the figure type such as rectangles and triangles.

When design pattern data used as the figure data is input to the reference image generation circuit 112, the data is developed into data for each figure. Then, the figure code, the figure dimensions, and others indicating the figure shape of the figure data are interpreted. The figure data is developed into design pattern image data of binary or multiple values as a pattern to be arranged in squares being in units of grids of predetermined quantization dimensions, and then is output. In other words, the reference image generation circuit 112 reads design data, calculates the occupancy of a figure in the design pattern, for each square obtained by virtually dividing the inspection region into squares in units of predetermined dimensions, and outputs n-bit occupancy data. For example, it is preferable to set one square as one pixel. Assuming that one pixel has a resolution of ½⁸ (= 1/256), the occupancy rate in each pixel is calculated by allocating sub-regions, each having 1/256 resolution, which correspond to the region of a figure arranged in the pixel. Then, it is generated as occupancy rate data of 8 bits. Such squares (inspection pixels) can be commensurate with pixels of measured data.

Next, the reference image generation circuit 112 performs filtering processing on design image data of a design pattern which is image data of a figure, using a predetermined filter function. Thereby, it becomes possible to match the design image data being design side image data, whose image intensity (gray scale level) is represented by digital values, with image generation characteristics obtained by irradiation with the multiple primary electron beams 20. The generated image data for each pixel of a reference image is output to the comparison circuit 108.

In the comparison circuit 108, for each frame region 30, a position alignment is performed based on units of sub-pixels between the frame image 31 (first image), being an image to be inspected, and the reference image (second image) corresponding to the frame image concerned. For example, the position alignment can be performed using a least-squares method.

The comparison unit 108 compares the frame image 31 (first image) and the reference image (second image). The comparison unit 108 compares them, for each pixel 36, based on predetermined determination conditions in order to determine whether there is a defect such as a shape defect. For example, if a difference in gray scale level for each pixel 36 is larger than a determination threshold Th, it is determined that there is a defect. Then, the comparison result may be output to the storage device 109, the monitor 117, or the memory 118, or alternatively, output from the printer 119.

In addition to the die-to-database inspection described above, it is also preferable to perform the die-to-die inspection which compares data of measured images acquired by imaging identical patterns at different positions on the same substrate. Alternatively, the inspection may be performed using only an own measurement image.

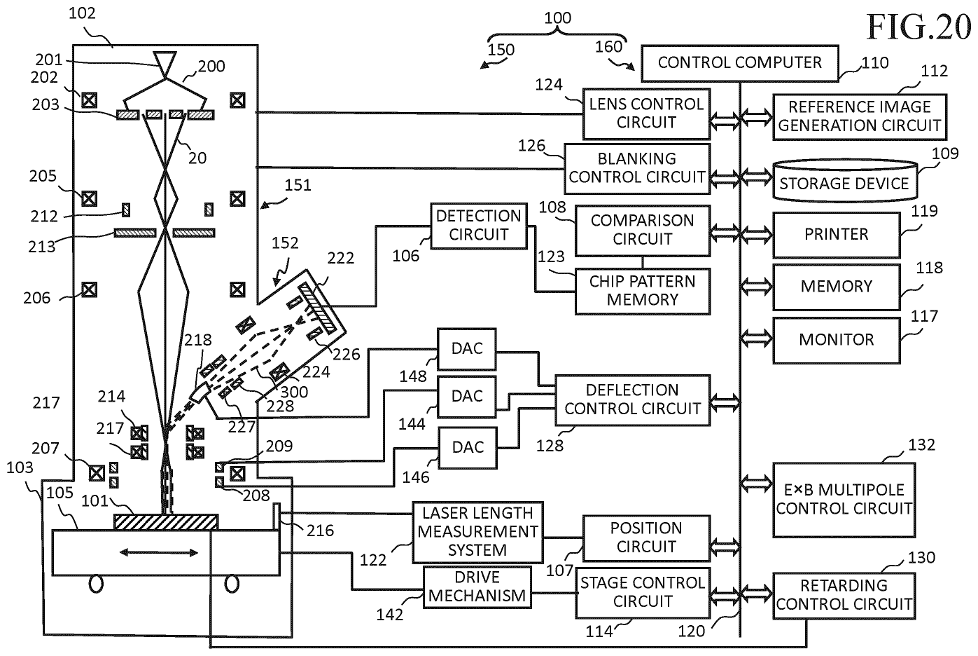

FIG. 20 is a configuration diagram of a pattern inspection apparatus according to a third modified example of the first embodiment. In the case of FIG. 20, as a plurality of multipole lenses, there is arranged a four-stage multipole lens composed of the first multipole lens, the second multipole lens, the third multipole lens, and the fourth multipole lens. In the four-stage multipole lens, the E×B multipole lenses 214 and 217 are arranged, similarly to FIG. 1, at positions common to the trajectory of the multiple primary electron beams 20 and that of the multiple secondary electron beams 300. Then, multipole lenses 227 and 228 are arranged in the middle of the trajectory of the multiple secondary electron beams 300 separated from the trajectory of the multiple primary electron beams 20. In the case of FIG. 20, the multipole lenses 227 and 228 are arranged between the deflector 218 and the electromagnetic lens 224. The multiple secondary electron beams 300 are separated from the trajectory of the multiple primary electron beams 20 by the E×B multipole lens 214 at a position being the farther from the substrate of the E×B multipole lenses 214 and 217.

By exerting an x-direction convergence effect and a y-direction divergence effect by the E×B multipole lens 217, and exerting an x-direction divergence effect and a y-direction convergence effect by the E×B multipole lens 214, imaging is performed at the position of the deflector 218. At this time, a magnification difference between the x and y directions is generated as described above. This magnification difference can be improved by arranging the multipole lenses 227 and 228 after the deflector 218. Specifically, by exerting an x-direction divergence effect and a y-direction convergence effect by the E×B multipole lens 227, and exerting an x-direction convergence effect and a y-direction divergence effect by the E×B multipole lens 228, improvement can be performed such that the magnification difference generated in the two E×B multipole lenses 214 and 217 is cancelled out by the multipole lenses 227 and 228. Similarly to the case of the multipole lens 221, it is sufficient for each of the multipole lenses 227 and 228 to include at least either of a plurality of four or more electrodes and a plurality of four or more magnetic poles. The magnification difference can also be adjusted by increasing the number of the multipole lenses arranged in the middle of the trajectory of the multiple secondary electron beams 300 separated from the trajectory of the multiple primary electron beams 20. The other contents are the same as those described above.

As described above, according to the first embodiment, it is possible to reduce aberration which is generated when multiple secondary electron beams are separated from multiple primary electron beams by an E×B separator.

In the above description, each “ . . . circuit” includes processing circuitry. The processing circuitry includes an electric circuit, a computer, a processor, a circuit board, a quantum circuit, a semiconductor device, or the like. Each “ . . . circuit” may use common processing circuitry (the same processing circuitry), or different processing circuitry (separate processing circuitry). Programs for causing a processor, etc. to execute processing may be stored in a recording medium, such as a magnetic disk drive, magnetic tape drive, FD, ROM (Read Only Memory) or the like. For example, the position circuit 107, the comparison circuit 108, the reference image generation circuit 112, and the like may be formed by at least one processing circuit described above.

Embodiments have been explained referring to specific examples described above. However, the present invention is not limited to these specific examples. For example, the electromagnetic lens 217 may be an electrostatic lens.

While the apparatus configuration, control method, and others not directly necessary for explaining the present invention are not described, some or all of them can be appropriately selected and used on a case-by-case basis when needed.

Further, any multi-electron beam image acquiring apparatus and multi-electron beam image acquiring method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-electron beam image acquiring apparatus comprising:
a stage configured to mount thereon a substrate;
an illumination optical system configured to apply multiple primary electron beams to the substrate;
a plurality of multipole lenses including at least two stages of multipole lenses, arranged at positions common to a trajectory of the multiple primary electron beams and a trajectory of multiple secondary electron beams which are emitted because the substrate is irradiated with the multiple primary electron beams and each configured to include at least four electrodes and at least four magnetic poles; and
a multi-detector configured to detect the multiple secondary electron beams separated from the trajectory of the multiple primary electron beams, wherein
one of the plurality of multipole lenses separates the multiple secondary electron beams from the trajectory of the multiple primary electron beams,
the plurality of multipole lenses exert, on the multiple secondary electron beams, one of lens effects of a divergence effect and a convergence effect, in a first direction perpendicular to a trajectory central axis of the multiple secondary electron beams, and exert an other of the lens effects of the divergence effect and the convergence effect, in a second direction perpendicular to the trajectory central axis of the multiple secondary electron beams, and
the one of the plurality of multipole lenses, which separates the multiple secondary electron beams from the trajectory of the multiple primary electron beams, separates the multiple secondary electron beams, in one of directions of the first direction and the second direction, which is associated with the divergence effect.

2. The apparatus according to claim 1, wherein
the plurality of multipole lenses include a first multipole lens and a second multipole lens,
further comprising:
a third multipole lens arranged in a middle of the trajectory of the multiple secondary electron beams separated from the trajectory of the multiple primary electron beams.

3. The apparatus according to claim 2, wherein
the third multipole lens includes, at least, either of at least four electrodes and at least four magnetic poles.

4. The apparatus according to claim 1, wherein
the plurality of multipole lenses include a first multipole lens, a second multipole lens, and a third multipole lens, and
the multiple secondary electron beams are separated from the trajectory of the multiple primary electron beams by one of the first multipole lens, the second multipole lens, and the third multipole lens, which is arranged at a position being farthest from the substrate.

5. A multi-electron beam image acquiring method comprising:
applying, by an illumination optical system, multiple primary electron beams to a substrate mounted on a stage;
exerting a lens effect on multiple secondary electron beams, which are emitted because the substrate is irradiated with the multiple primary electron beams, by a plurality of multipole lenses including at least two stages of multipole lenses and each including at least four electrodes and at least four magnetic poles;
separating the multiple secondary electron beams from a trajectory of the multiple primary electron beams by one of the plurality of multipole lenses; and
detecting the multiple primary electron beams having been separated, wherein
the plurality of multipole lenses exert, on the multiple secondary electron beams, one of lens effects of a divergence effect and a convergence effect, in a first direction perpendicular to a trajectory central axis of the multiple secondary electron beams, and exert an other of the lens effects of the divergence effect and the convergence effect, in a second direction perpendicular to the trajectory central axis of the multiple secondary electron beams, and
the one of the plurality of multipole lenses, which separates the multiple secondary electron beams from the trajectory of the multiple primary electron beams, separates the multiple secondary electron beams, in one of directions of the first direction and the second direction, which is associated with the divergence effect.

6. The method according to claim 5, wherein
the plurality of multipole lenses include a first multipole lens and a second multipole lens,
further comprising:
reversing the lens effect exerting on the multiple secondary electron beams by a third multipole lens arranged in a middle of a trajectory of the multiple secondary electron beams separated from the trajectory of the multiple primary electron beams.

7. The method according to claim 6, wherein
the third multipole lens includes, at least, either of at least four electrodes and at least four magnetic poles.

8. The method according to claim 5, wherein
the plurality of multipole lenses include a first multipole lens, a second multipole lens, and a third multipole lens, and
the multiple secondary electron beams are separated from the trajectory of the multiple primary electron beams by one of the first multipole lens, the second multipole lens, and the third multipole lens, which is arranged at a position being farthest from the substrate.

9. The apparatus according to claim 1, wherein
the plurality of multipole lenses include a first multipole lens and a second multipole lens,
further comprising:
a plurality of multipole lenses arranged in a middle of the trajectory of the multiple secondary electron beams separated from the trajectory of the multiple primary electron beams.

10. The apparatus according to claim 9, wherein
the plurality of multipole lenses arranged in the middle of the trajectory of the multiple secondary electron beams separated from the trajectory of the multiple primary electron beams include a third multipole lens and a fourth multipole lens.

11. The apparatus according to claim 10, wherein
each of the third multipole lens and the fourth multipole lens includes, at least, either of at least four electrodes and at least four magnetic poles.
